(19) United States
(12) Patent Application Publication
(10) Pub. No.: US 2025/0295022 A1
(43) Pub. Date: Sep. 18, 2025

(54) QUANTUM DOT COMPOSITION, LIGHT-EMITTING ELEMENT, DISPLAY PANEL AND PREPARATION METHOD THEREOF

(71) Applicants: Beijing BOE Technology Development Co., Ltd., Beijing (CN); BOE Technology Group Co., Ltd., Beijing (CN)

(72) Inventors: Zhuo CHEN, Beijing (CN); Shaoyong LU, Beijing (CN); Xiangbing FAN, Beijing (CN); Xiaoyuan ZHANG, Beijing (CN)

(73) Assignees: Beijing BOE Technology Development Co., Ltd., Beijing (CN); BOE Technology Group Co., Ltd., Beijing (CN)

(21) Appl. No.: 19/101,671

(22) PCT Filed: Feb. 28, 2024
(86) PCT No.: PCT/CN2024/079096

§ 371 Date: Feb. 6, 2025

(30) Foreign Application Priority Data
Feb. 7, 2024 (WO) PCT/CN2024/076770

(51) Int. Cl. H10K 85/30; B82Y 20/00; B82Y 40/00; C09K 11/02; H10K 50/115; H10K 71/10

(52) U.S. Cl. CPC H10K 85/30; C09K 11/025; B82Y 20/00; B82Y 40/00; H10K 50/115; H10K 71/10

(57) ABSTRACT

A quantum dot composition includes a quantum dot body, a ligand, and a crosslinking agent; the ligand being coordinately connected with the quantum dot body; one of the ligand and the crosslinking agent having a thiol group protected by a photolyzable group; the photolyzable group being removable under light to release the thiol group, a sulfur free radical or a sulfur anion; when the released thiol group, sulfur free radical or sulfur anion is located on the crosslinking agent, the released thiol group, sulfur free radical or sulfur anion being used for coordinating with the quantum dot body or used for reacting with the ligand to form a chemical bond; when the released thiol group, sulfur free radical or sulfur anion is located on the ligand, the released thiol group, sulfur free radical or sulfur anion being used for reacting with the crosslinking agent to form a chemical bond.

### CROSS-REFERENCE TO RELATED APPLICATIONS

The present disclosure is a U.S. National Stage Application of International Application No. PCT/CN2024/079096, filed on Feb. 28, 2024, which is based upon and claims priority to PCT/CN2024/076770, filed Feb. 7, 2024, entitled “Quantum dot composition, light-emitting element, display panel and preparation method thereof”, the entire contents of each are incorporated herein by reference.

### TECHNICAL FIELD

The present disclosure relates to the field of display technologies, and in particular, to a quantum dot composition, a light-emitting element, a display panel and a preparation method thereof.

### BACKGROUND

With the development of the preparation technology of quantum dots, the continuously improved of stability and luminous efficiency of quantum dots, and the continuous deepening research on quantum dot electroluminescent diodes (QLEDs), the application prospect of QLEDs in the field of display is increasingly bright. However, the efficiency of QLED has not yet reached the level of mass production. One important reason is that the high-resolution patterning technology of QLED has not yet made a breakthrough. The inorganic nanoparticle feature of the quantum dot makes it difficult to form films and pattern them through evaporation, and also difficult to achieve high resolution through inkjet printing.

It should be noted that the information disclosed in the Background section above is only for enhancing the understanding of the background of the present disclosure, and thus may include information that does not constitute prior art known to those of ordinary skill in the art.

### SUMMARY

An object of the present disclosure is to provide a quantum dot composition, a light-emitting element, a display panel and a preparation method thereof, which are used for preparing a display panel by a photolithography process.

According to an aspect of the present disclosure, a quantum dot composition is provided, which includes a quantum dot body, a ligand, and a crosslinking agent;
the ligand is coordinately connected with the quantum dot body;
wherein one of the ligand and the crosslinking agent has a thiol group protected by a photolyzable group;
the photolyzable group can be removed under light to release the thiol group, a sulfur free radical or a sulfur anion;
when the released the thiol group, sulfur free radical or sulfur anion is located on the crosslinking agent, the released thiol group, sulfur free radical or sulfur anion is used for coordinately connecting with the quantum dot body or used for reacting with the ligand to form a chemical bond; when the released thiol group, sulfur free radical or sulfur anion is located on the ligand, the released thiol group, sulfur free radical or sulfur anion is used for reacting with the crosslinking agent to form a chemical bond.

According to an embodiment of the present disclosure, the photolyzable group is selected from the following substituents:

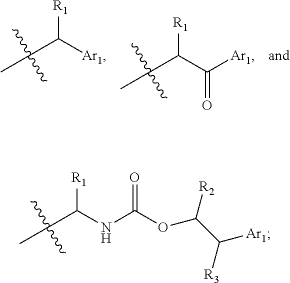

wherein Ar₁ is selected from an aryl group having a nitro group or a hydroxyl group, a heteroaryl group having a nitro group and a hydroxyl group; R₁, R₂ and R₃ are each independently selected from hydrogen, deuterium and an alkyl group having a carbon atom number of 1 to 6.

According to an embodiment of the present disclosure, the photolyzable group is selected from the following substituents:

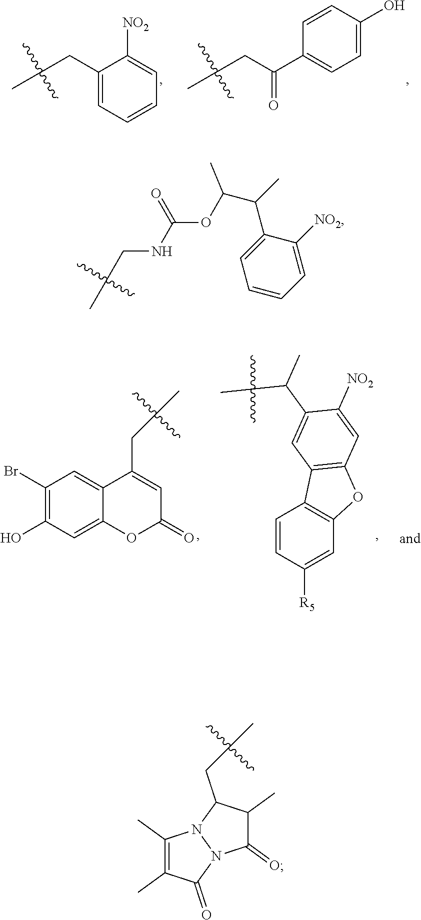

wherein R₅ is selected from hydrogen, deuterium, and alkoxy having a carbon atom of 1 to 8.

According to an embodiment of the present disclosure, the crosslinking agent has a plurality of thiol groups protected by the photolyzable group; the ligand has an active alkenyl group, and the active alkenyl group has an alkenyl group and an electron-withdrawing group connected to the alkenyl group.

According to an embodiment of the present disclosure, the crosslinking agent has a first connecting group, and the thiol group protected by photolyzable group is attached to the first connecting group.

According to an embodiment of the present disclosure, a structural formula of the ligand is A-B-C-D or A-B-D; wherein, A is a coordination group capable of coordinately connected with the quantum dot; B is a second connecting group; and C is a carrier transport adjustment group; D is the active alkenyl group.

According to an embodiment of the present disclosure, the ligand has the thiol group protected by photolyzable group; the crosslinking agent has a plurality of active alkenyl groups, and the active alkenyl group has an alkenyl group and an electron-withdrawing group connected to the alkenyl group.

According to an embodiment of the present disclosure, the crosslinking agent has a first connecting group, and the active alkenyl group is attached to the first connecting group.

According to an embodiment of the present disclosure, a structural formula of the ligand is A-B-C-D or A-B-D; wherein, A is a coordination group capable of coordinately connected with the quantum dot; B is a second connecting group; C is a carrier transport adjustment group; D is the thiol group protected by photolyzable group.

According to an embodiment of the present disclosure, the coordination group has an amino group, a carboxylic acid group, a thiol group, two thiol groups, a phosphine group, or a phosphine oxide group.

According to an embodiment of the present disclosure, the active alkenyl group is selected from the group consisting of:

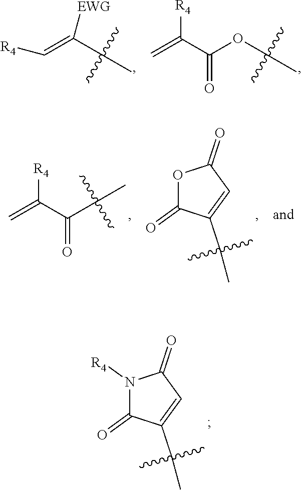

wherein R₄ is selected from the group consisting of hydrogen, deuterium and alkyl groups of 1 to 6 carbon atoms; EWG is an electron-withdrawing group.

According to an embodiment of the present disclosure, the active alkenyl group is selected from the group consisting of:

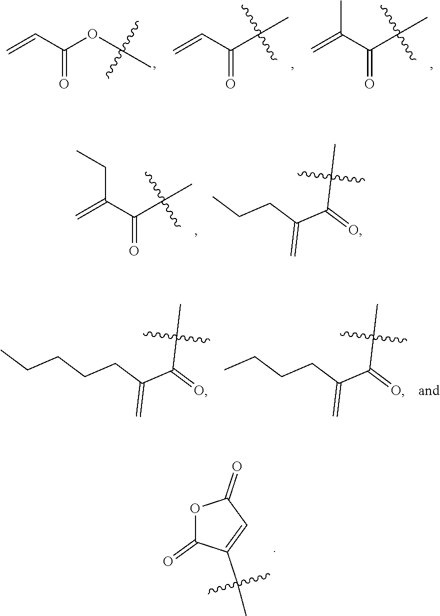

According to an embodiment of the present disclosure, the crosslinking agent has a plurality of thiol groups protected by the photolyzable group;
in the quantum dot body and the ligand, the mass ratio of the ligand is not greater than 30%.

According to an embodiment of the present disclosure, in the quantum dot body and the ligand, the mass ratio of the ligand is not greater than 15%.

According to an embodiment of the present disclosure, in the quantum dot body and the ligand, the mass ratio of the ligand is between 15% and 30%;
the acidity of the ligand is less than the acidity of the thiol group protected by photolyzable group after deprotection.

According to an embodiment of the present disclosure, the ligand is selected from oleic acid, oleylamine, octanethiol group, and dodecanethiol group.

According to an embodiment of the present disclosure, the mass content of the crosslinking agent is 1% to 5%.

According to the second aspect of the present disclosure, a light-emitting element is provided, wherein the light-emitting element includes a quantum dot layer; the quantum dot layer includes quantum dot bodies connected to each other by organic materials;
the organic material includes a ligand group coordinately connected with the quantum dot body and a crosslinking group connected with a plurality of ligand groups, and a thioether structure is formed between the ligand group and the crosslinking group; or the organic material has a plurality of thiol groups, sulfur free radicals or sulfur anions and is coordinately connected with a plurality of quantum dot bodies through thiol groups, sulfur free radicals or sulfur anions.

According to the third aspect of the present disclosure, there is provided a display panel, including the above light-emitting element.

According to the fourth aspect of the present disclosure, a preparation method of a display panel is provided, which includes: forming a quantum dot layer of at least two sub-pixels sequentially through a photolithography process on a surface of a substrate; and forming a quantum dot layer of any of the sub-pixels includes:
forming a quantum dot composition film on a surface of the substrate by using a quantum dot composition corresponding to the sub-pixel, where the quantum dot composition is selected from the quantum dot composition described above;
exposing and developing the quantum dot composition film corresponding to the sub-pixel to obtain a quantum dot layer of the sub-pixel;
wherein, quantum dots in quantum dot compositions corresponding to quantum dot layers of different sub-pixels are different.

According to an embodiment of the present disclosure, the preparation method of the display panel further includes:
forming a hole transport layer of each of the sub-pixels before forming the quantum dot layer.

According to an embodiment of the present disclosure, the preparation method of the display panel further includes:
forming an electron transport layer of each of the sub-pixels is formed after forming the quantum dot layer of each of the sub-pixels.

According to an embodiment of the present disclosure, forming the quantum dot composition film on the surface of the substrate by using the quantum dot composition corresponding to the sub-pixel includes:
forming the quantum dot composition film on the surface of the substrate by a coating process by using the quantum dot composition corresponding to the sub-pixel.

It should be noted that the above general description and the following detailed description are merely exemplary and explanatory and should not be construed as limiting of the disclosure.

### BRIEF DESCRIPTION OF THE DRAWINGS

The drawings here are incorporated into the specification and constitute a part of the specification, show embodiments in consistent with the present disclosure, and are used together with the specification to explain principles of the present disclosure. Obviously, the drawings in the following description are only some embodiments of the present disclosure. For those of ordinary skill in the art, other drawings can be obtained based on these drawings without creative work.

FIG. 1 is a schematic flowchart of preparing a quantum dot layer in an embodiment of the present disclosure.

FIG. 2 is a schematic structural diagram of a surface of a back plate having a pixel definition layer in an embodiment of the present disclosure.

FIG. 3 is a schematic structural diagram of forming a green quantum dot composition layer on a surface of a back plate in an embodiment of the present disclosure.

FIG. 4 is a schematic structural diagram of forming a green quantum dot layer on a surface of a back plate in an embodiment of the present disclosure.

FIG. 5 is a schematic structural diagram of forming a blue quantum dot composition layer on a surface of a back plate in an embodiment of the present disclosure.

FIG. 6 is a schematic structural diagram of forming a blue quantum dot layer on a surface of a back plate in an embodiment of the present disclosure.

FIG. 7 is a schematic structural diagram of forming a red quantum dot composition layer on a surface of a back plate in an embodiment of the present disclosure.

FIG. 8 is a schematic structural diagram of forming a red quantum dot layer on a surface of a back plate in an embodiment of the present disclosure.

FIG. 9 is an ultraviolet excitation result diagram of a substrate after coating, exposure and development on a glass substrate using a control quantum dot composition.

FIG. 10 is an ultraviolet excitation result diagram of a substrate after coating, exposure and development on a glass substrate by using an experimental quantum dot composition.

### DETAILED DESCRIPTION

Example embodiments will now be described more fully with reference to the accompanying drawings. However, the example embodiments can be embodied in a variety of forms and should not be construed as limited to the embodiments set forth herein; rather, these embodiments are provided so that the present disclosure will be thorough and complete and fully convey the concepts of the example embodiments to those skilled in the art. The described features, structures, or characteristics may be incorporated in one or more embodiments in any suitable manner. In the following description, numerous specific details are provided to give a thorough understanding of embodiments of the present disclosure. However, those skilled in the art will recognize that the technical solutions of the present disclosure may be practiced without one or more of the specific details, or other methods, components, materials, and the like may be employed. In other instances, well-known structures, materials, or operations are not shown or described in detail to avoid obscuring the main technical creative of the present disclosure.

Like reference numerals refer to the same or similar structures, and detailed description thereof will be omitted. In addition, the drawings are merely schematic illustrations of the present disclosure and are not necessarily drawn to scale.

When a structure is “on” another structure, it may mean that a structure is integrally formed on another structure, or a structure “directly” is disposed on another structure, or a structure is “indirectly” disposed on another structure through another structure.

The terms “a”, “an”, “the”, “said”, and “at least one” are used to indicate that there are one or more elements/components/and the like; the terms “including” and “having” are used to refer to an open-ended inclusion and refer to that there may be additional elements/components/and the like in addition to the listed elements/components/and the like; the terms “first”, “second”, “third”, and the like are used only as labels, not to the number of objects thereof.

In the related art, since the quantum dots are easily affected by heat and moisture, the same evaporation mode as the self-luminous OLED cannot be achieved, and only ink-jet printing can be used. However, it is difficult to achieve higher resolution by inkjet printing.

In order to solve the above problems, an embodiment of the present disclosure provides a quantum dot composition, which includes a quantum dot body, a ligand, and a crosslinking agent; the ligand is coordinately connected with the quantum dot body; wherein one of the ligand and the crosslinking agent has a thiol group protected by a photolyzable group; the photolyzable group can be removed under light to release an active sulfur group, and the active sulfur group can chemically react with other components in the quantum dot composition to form a chemical bond. For example, the photolyzable group can release a thiol group, a sulfur free radical or a sulfur anion under light. When the released thiol group, sulfur free radical or sulfur anion are located on the crosslinking agent, the released thiol group, sulfur free radical or sulfur anion is used for coordinately connected with the quantum dot body or used for reacting with the ligand to form a chemical bond; when the released thiol group, sulfur free radical or sulfur anion is located on the ligand, the released thiol group, sulfur free radical or sulfur anion is used for reacting with the crosslinking agent to form a chemical bond.

In the quantum dot composition provided by the present disclosure, the quantum dot ligand or the crosslinking agent contains sulfydryl protected by photopleable Protecting Group (PPG), and when the quantum dot composition is applied, photolysis protection group PPG can be removed under light conditions to release thiol group, sulfur free radical or sulfur anion. The released thiol group, sulfur free radical or sulfur anion may further react with other components in the quantum dot composition, such that the quantum dot body may form a quantum dot layer by crosslinking. For example, the thiol group, sulfur free radical or sulfur anion released on the crosslinking agent may be directly coordinately connected to the coordination center of the surface of the quantum dot body. For another example, the thiol group, sulfur free radical or sulfur anion released on the crosslinking agent may also react with the quantum dot ligand. For another example, thiol group, sulfur free radical or sulfur anion released on the quantum dot ligand may react with the crosslinking agent. Thus, the quantum dot composition of the present disclosure can crosslink under light, but does not crosslink under no light, which allows the film prepared from the quantum dot composition to be patterned using a photolithography process. When the display panel adopts the quantum dot composition of the present disclosure and a photolithography process is used to prepare the quantum dot layer, the restriction of inkjet printing on the resolution can be reduced, thereby facilitating improvement of the resolution of the display panel.

Quantum dots (QDs) are small-sized inorganic semiconductor nanoparticles that are approximately or smaller than the exciton Bohr radius of the particles. The quantum dots are very small in size, large in specific surface area and easy to agglomerate, and the surface defects of the quantum dots are relatively large, so the surface of the quantum dots is usually modified with ligands to form modified quantum dots when applied. In an embodiment of the present disclosure, an unmodified inorganic quantum dot is referred to as a quantum dot body, and a material modified on the quantum dot body is referred to as a ligand. The ligand is generally an organic ligand. The organic ligand not only provides protection but also allows quantum dots to have good solubility in solution. Migration of carriers (electrons and holes) in the quantum dots is confined inside the quantum dots, such that the quantum dots have unique optical and electrical properties. Due to unique dimension-dependent properties, the light-absorbing properties and luminescence properties of the quantum dots can be readily adjusted by controlling the particle size, shape, or surface structure.

The quantum dots of the present disclosure may be semiconductor nanocrystals and may have a variety of shapes. For example, it can be spherical, conical, multi armed, and/or cubic nanoparticles, nanotubes, nanowires, nanofibers, nanoplate particles, quantum rods, or quantum sheets. Here, the aspect ratio (aspect ratio; length to width ratio) of the quantum rods may be greater than about 1. For example, the aspect ratio of the quantum rods is greater than or equal to about 2, greater than or equal to about 3, or greater than or equal to about 5. For example, the quantum rods may have an aspect ratio of less than or equal to about 50, less than or equal to about 30, or less than or equal to about 20.

The quantum dot body may have a particle diameter (for non-spherical shape, average maximum particle length) of, for example, about 1 nm to about 100 nm, about 1 nm to about 80 nm, about 1 nm to about 50 nm, or about 1 nm to 20 nm, or 1 nm to 10 nm.

Exemplarily, the energy bandgap of the quantum dot body can be controlled according to the size and composition of the quantum dot body, and thus the emission wavelength can be controlled. For example, when the size of the quantum dot body increases, the quantum dot body may have a narrow bandgap and thus be configured to emit light in a relatively long wavelength region, whereas when the size of the quantum dot body decreases, the quantum dot body may have a wide bandgap and thus be configured to emit light in a relatively short wavelength region. Exemplarily, the quantum dot body may be configured to emit light in a predetermined wavelength region of the visible light region according to its size and/or composition. For example, the quantum dot body may be configured to emit a second color light, a third color light, or a first color light, the second color light may have a peak emission wavelength (k max), e.g., in the range of about 430 nm to about 480 nm, the third color light may have a peak emission wavelength (k max), e.g., in the range of about 600 nm to about 650 nm, and the first color light may have a peak emission wavelength (k max), e.g., in the range of about 520 nm to about 560 nm, but is not limited thereto.

Exemplarily, the average particle size of the quantum dot body configured to emit the second color light may be less than or equal to about 4.5 nm; for example, the average particle size of the quantum dot body configured to emit the second color light may be less than or equal to about 4.3 nm, less than or equal to about 4.2 nm, less than or equal to about 4.1 nm, or less than or equal to about 4.0 nm. Within the range, the quantum dot body may have an average particle size of about 2.0 nm to about 4.5 nm, such as about 2.0 nm to about 4.3 nm, about 2.0 nm to about 4.2 nm, about 2.0 nm to about 4.1 nm, or about 2.0 nm to about 4.0 nm.

Exemplarily, the quantum dot body may have a quantum yield of greater than or equal to about 10%, greater than or equal to about 20%, greater than or equal to about 30%, greater than or equal to about 50%, greater than or equal to about 60%, greater than or equal to about 70%, or greater than or equal to about 90%.

The quantum dot body may have a relatively narrow half-width (FWHM). Here, the FWHM is the width of the wavelength corresponding to half of the peak absorption point, and when the FWHM is narrow, the FWHM may be configured to emit light in the narrower wavelength region, and higher color purity may be obtained. For example, the quantum dot body may have a FWHM of less than or equal to about 50 nm, less than or equal to about 49 nm, less than or equal to about 48 nm, less than or equal to about 47 nm, less than or equal to about 46 nm, less than or equal to about 45 nm, less than or equal to about 44 nm, less than or equal to about 43 nm, less than or equal to about 42 nm, less than or equal to about 41 nm, less than or equal to about 40 nm, less than or equal to about 39 nm, less than or equal to about 38 nm, less than or equal to about 37 nm, less than or equal to about 36 nm, less than or equal to about 35 nm, less than or equal to about 34 nm, less than or equal to about 33 nm, less than or equal to about 32 nm, less than or equal to about 31 nm, less than or equal to about 30 nm, less than or equal to about 29 nm, or less than or equal to about 28 nm. Exemplary, within the range, it can have a FWHM of about 2 nm to about 49 nm, about 2 nm to about 48 nm, about 2 nm to about 47 nm, about 2 nm to about 46 nm, about 2 nm to about 45 nm, about 2 nm to about 44 nm, about 2 nm to about 43 nm, about 2 nm to about 42 nm, about 2 nm to about 41 nm, about 2 nm to about 40 nm, about 2 nm to about 39 nm, about 2 nm to about 38 nm, about 2 nm to about 37 nm, about 2 nm to about 36 nm, about 2 nm to about 35 nm, about 2 nm to about 34 nm, about 2 nm to about 33 nm, about 2 nm to about 32 nm, about 2 nm to about 31 nm, about 2 nm to about 30 nm, about 2 nm to about 29 nm, or about 2 nm to about 28 nm.

Exemplarily, the quantum dot body may include a II-VI semiconductor compound, a III-V semiconductor compound, a IV-VI semiconductor compound, a IV semiconductor, an I-III-VI semiconductor compound, an I-II-IV-VI semiconductor compound, a II-IV-VI semiconductor compound, or a combination thereof. For example, the II-VI semiconductor compound may be selected from the group consisting of binary semiconductor compounds such as CdSe, CdTe, ZnS, ZnSe, ZnTe, ZnO, HgS, HgSe, HgTe, MgSe, MgS, or mixtures thereof; ternary semiconductor compounds such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, or mixtures thereof; and quaternary semiconductor compounds such as HgZnTeS, CdZnSeS, CdZnSeTe, CdZnSTe, CdHgSeS, CdHgSeTe, CdHgSTe, HgZnSeS, HgZnSeTe, HgZnSTe, or mixtures thereof, but are not limited thereto. For another example, the III-V semiconductor compound may be selected from the group consisting of binary semiconductor compounds such as GaN, GaP, GaAs, GaSb, AlN, AlP, AlAs, AlSb, InN, InP, InAs, InSb, or mixtures thereof; ternary semiconductor compounds such as GaNP, GaNAs, GaNSb, GaPAs, GaPSb, AlNP, AlNAs, AlNSb, AlPAs, AlPSb, InNP, InNAs, InNSb, InPAs, InPSb, or mixtures thereof; and quaternary semiconductor compounds such as GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, or mixtures thereof, but are not limited thereto. For another example, the group IV-VI semiconductor compound may be selected from a binary semiconductor compound such as SnS, SnSe, SnTe, PbS, PbSe, PbTe, or a mixture thereof; a ternary semiconductor compound such as SnSeS, SnSeTe, SnSTe, PbSeS, PbSeTe, PbSTe, SnPbS, SnPbSe, SnPbTe, or a mixture thereof; and a quaternary semiconductor compound such as SnPbSSe, SnPbSeTe, SnPbSTe, or a mixture thereof, but is not limited thereto. The group IV semiconductor may, for example, be selected from the group consisting of elementary (unary) semiconductors such as Si, Ge, or mixtures thereof; and binary semiconductor compounds such as SiC, SiGe, and mixtures thereof, but are not limited thereto. The I-III-VI semiconductor compound may be, for example, CuInSe₂, CuInS₂, CuInGaSe, CuInGaS, or a mixture thereof, but is not limited thereto. The I-II-IV-VI semiconductor compound may be, for example, CuZnSnSe, CuZnSnS, or a mixture thereof, but is not limited thereto. The II-III-V semiconductor compound may include, for example, InZnP, but is not limited thereto.

The quantum dot body may include the elemental semiconductor, the binary semiconductor compound, the ternary semiconductor compound, or the quaternary semiconductor compound at a substantially uniform concentration or locally different concentration profile.

For example, the quantum dot body may include a cadmium-free (Cd) quantum dot body. The cadmium-free quantum dot body is a quantum dot body that does not include cadmium (Cd). Cadmium (Cd) can cause serious environmental/health problems, and in many countries, cadmium (Cd) is an element that is limited by Restriction of Hazardous Substances (RoHS).

Exemplarily, the quantum dot body may be a semiconductor compound including at least one of zinc (Zn) and tellurium (Te) and selenium (Se). For example, the quantum dot body may be a Zn—Te semiconductor compound, a Zn—Se semiconductor compound, and/or a Zn—Te—Se semiconductor compound. For example, the amount of tellurium (Te) in the Zn—Te—Se semiconductor compound may be less than the amount of selenium (Se). The semiconductor compound may have a peak emission wavelength (λ max) in a wavelength region of less than or equal to about 480 nm, e.g., about 430 nm to about 480 nm, and may be configured to emit the second color light.

Exemplarily, the quantum dot body may be a semiconductor compound including at least one of indium (In) and zinc (Zn) and phosphorus (P). For example, the quantum dot body may be an In—P semiconductor compound and/or an In—Zn—P semiconductor compound.

In the compound, the molar ratio of zinc (Zn) to indium (In) may be greater than or equal to about 25. The semiconductor compound may have a peak emission wavelength (λ max) in a wavelength region of less than about 700 nm, e.g., about 600 nm to about 650 nm, and may be configured to emit the third color light.

The quantum dot body may have a core-shell structure. For example, a core and a shell of the quantum dot body may have an interface, and elements of at least one of the core or the shell in the interface may have a concentration gradient, wherein the concentration of elements of the shell decreases toward the core. For example, the material composition of the shell of the quantum dot body has a higher energy bandgap than the material composition of the core of the quantum dot body, and thus the quantum dot body can exhibit a quantum confinement effect.

The quantum dot body may have a quantum dot core and a multilayer quantum dot shell surrounding the core. Here, the multilayer shell has at least two shells, wherein each shell may be a single composition, an alloy, and/or have a concentration gradient.

For example, a shell of the multilayer shell that is far away from the core may have a higher energy bandgap than a shell that is close to the core, and thus the quantum dot body may exhibit a quantum confinement effect.

For example, the quantum dot body having a core-shell structure may, for example, include a core including a first semiconductor compound including at least one of zinc (Zn), and tellurium (Te) and selenium (Se); and a shell including a second semiconductor compound disposed on at least a portion of the core and having a composition different from the composition of the core.

For example, the first semiconductor compound may be a Zn—Te—Se based semiconductor compound including zinc (Zn), tellurium (Te), and selenium (Se), for example, a Zn—Se based semiconductor compound including a small amount of tellurium (Te), e.g., a semiconductor compound represented by ZnTexSe1-x, where x is greater than about 0 and less than or equal to 0.05.

For example, in the first semiconductor compound based on Zn—Te—Se, the molar amount of zinc (Zn) may be higher than the molar amount of selenium (Se), and the molar amount of selenium (Se) may be higher than the molar amount of tellurium (Te). For example, in the first semiconductor compound, the molar ratio of tellurium (Te) to selenium (Se) may be less than or equal to about 0.05, less than or equal to about 0.049, less than or equal to about 0.048, less than or equal to about 0.047, less than or equal to about 0.045, less than or equal to about 0.044, less than or equal to about 0.043, less than or equal to about 0.042, less than or equal to about 0.041, less than or equal to about 0.04, less than or equal to about 0.039, less than or equal to about 0.035, less than or equal to about 0.03, less than or equal to about 0.029, less than or equal to about 0.025, less than or equal to about 0.024, less than or equal to about 0.023, less than or equal to about 0.022, less than or equal to about 0.021, less than or equal to about 0.02, less than or equal to about 0.019, less than or equal to about 0.018, less than or equal to about 0.017, less than or equal to about 0.016, less than or equal to about 0.015, less than or equal to about 0.014, less than or equal to about 0.013, less than or equal to about 0.012, less than or equal to about 0.011, or less than or equal to about 0.01. For example, in the first semiconductor compound, the molar ratio of tellurium (Te) to zinc (Zn) may be less than or equal to about 0.02, less than or equal to about 0.019, less than or equal to about 0.018, less than or equal to about 0.017, less than or equal to about 0.016, less than or equal to about 0.015, less than or equal to about 0.014, less than or equal to about 0.013, less than or equal to about 0.012, less than or equal to about 0.011, or less than or equal to about 0.010.

The second semiconductor compound may include, for example, a II-VI semiconductor compound, a III-V semiconductor compound, a IV-VI semiconductor compound, an IV semiconductor, an I-III-VI semiconductor compound, an I-II-IV-VI semiconductor compound, a II-II-VI semiconductor compound, or a combination thereof. Examples of the II-VI semiconductor compound, the III-V semiconductor compound, the IV-VI semiconductor compound, the group IV semiconductor, the I-III-VI semiconductor compound, the I-II-IV-VI semiconductor compound, and the II-III-V semiconductor compound are the same as described above.

For example, the second semiconductor compound may include zinc (Zn), selenium (Se), and/or sulfur (S). For example, the shell may include ZnSeS, ZnSe, ZnS, or a combination thereof. For example, the shell may include at least one inner shell disposed near the core and an outermost shell disposed at an outermost side of the quantum dot body. The inner shell may include ZnSeS, ZnSe, or a combination thereof, and the outermost shell may include ZnS. For example, the shell may have a concentration gradient of one component and, for example, the amount of sulfur (S) may increase as it leaves the core.

For example, the quantum dot body having a core-shell structure may include a core including a third semiconductor compound including indium (In), and at least one of zinc (Zn) and phosphorus (P); and a shell disposed on at least a portion of the core and including a fourth semiconductor compound having a composition different from the composition of the core.

In the In—Zn—P based third semiconductor compound, the molar ratio of zinc (Zn) to indium (In) may be greater than or equal to about 25. For example, in the In—Zn—P based third semiconductor compound, the molar ratio of zinc (Zn) to indium (In) may be greater than or equal to about 28, greater than or equal to about 29, or greater than or equal to about 30. For example, in the In—Zn—P based third semiconductor compound, the molar ratio of zinc (Zn) to indium (In) may be less than or equal to about 55, such as less than or equal to about 50, less than or equal to about 45, less than or equal to about 40, less than or equal to about 35, less than or equal to about 34, less than or equal to about 33, or less than or equal to about 32.

The fourth semiconductor compound may include, for example, a II-VI semiconductor compound, a III-V semiconductor compound, a IV-VI semiconductor compound, an IV semiconductor, an I-III-VI semiconductor compound, an I-II-IV-VI semiconductor compound, a II-IV-VI semiconductor compound, or a combination thereof. Examples of the II-VI semiconductor compound, the III-V semiconductor compound, the IV-VI semiconductor compound, the group IV semiconductor, the I-III-VI semiconductor compound, the I-II-IV-VI semiconductor compound, and the II-III-V semiconductor compound are the same as described above.

For example, the fourth semiconductor compound may include zinc (Zn) and sulfur (S) and optionally selenium (Se). For example, the shell may include ZnSeS, ZnSe, ZnS, or a combination thereof. For example, the shell may include at least one inner shell disposed near the core and an outermost shell disposed at an outermost side of the quantum dot body. At least one of the inner shell and the outermost shell may include a fourth semiconductor compound ZnS, ZnSe, or ZnSeS.

In the present disclosure, for the sake of brevity and clarity, the schematic diagrams of the quantum dot bodies involved in the whole are all represented by circles, and the quantum dot body materials used in practice are not limited to spherical quantum dots, including but not limited to spherical, ellipsoidal, polyhedral, rod-shaped, cross-shaped, annular and other quantum dot materials having any geometric shape.

In some embodiments of the present disclosure, the photolyzable group is selected from the following substituents:

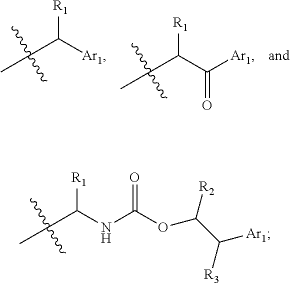

wherein Ar₁ is selected from an aryl group having a nitro group or a hydroxyl group, a heteroaryl group having a nitro group or a hydroxyl group; R₁, R₂ and R₃ are each independently selected from hydrogen, deuterium and an alkyl group having a carbon atom number of 1 to 6.

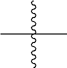

represents a chemical bond. Under the light condition, the photolyzable group releases thiol group, sulfur free radical or sulfur anion.

In an embodiment of the present disclosure, the photolyzable group is selected from the following substituents:

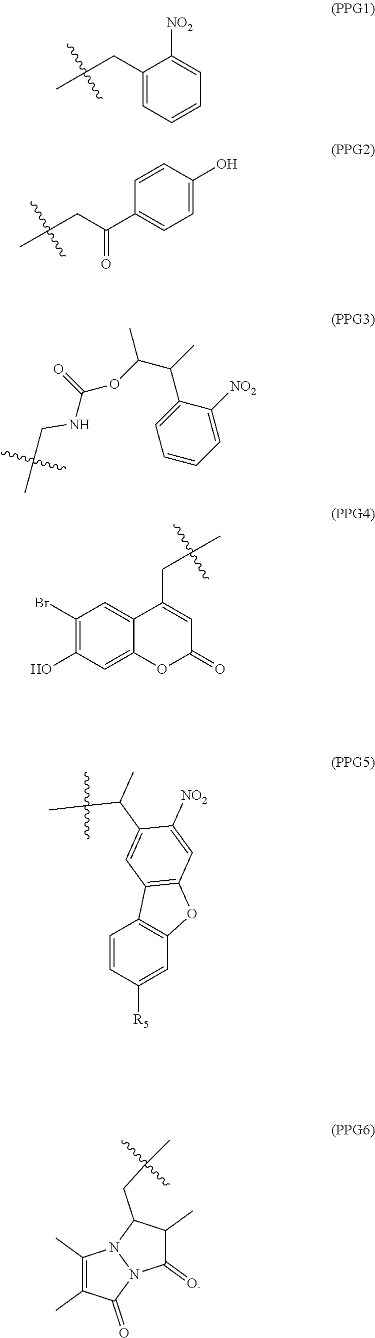

R₅ is selected from the group consisting of hydrogen, deuterium and alkoxy having a carbon atom of 1 to 8, for example, R₅ is selected from hydrogen, deuterium, —OCₙH₂ₙ₊₁ (n=1 to 8 positive integer). In an example, R₅ is selected from the group consisting of hydrogen, deuterium, methoxy, ethoxy, propoxy, isopropoxy, tert-butoxy, and the like.

It can be understood that the structure of the photolyzable group is different, and the light wavelength (i.e., the exposure wavelength) required during deprotection is different. For example, the exposure wavelength of PPG1 may be 320 nm or 365 nm; the exposure wavelength of PPG2 and PPG3 may be 254 nm; the exposure wavelength of PPG4 and PPG5 may be 365 nm; and the exposure wavelength of PPG6 may be 405 nm or 436 nm. The absorption wavelength and absorbance of the photolyzable group can also be adjusted by increasing or decreasing the substituent on the photolyzable group, so as to adapt to a wider process flow.

In some embodiments of the present disclosure, the crosslinking agent has a plurality of thiol groups protected by photolyzable groups; that is, the crosslinking agent contains two or more thiol groups protected by photolyzable groups. The quantum dot ligand has an active alkenyl group having an alkenyl group and an electron-withdrawing group attached to the alkenyl group. The crosslinking agent removes the protecting group (photolyzable group) under light to release thiol group, sulfur free radical or sulfur anion, which can react with the alkenyl in the active alkenyl group to generate chemical bonds. In this way, at least part of the cross-linking agent is cross-linked with ligands on different quantum dot bodies, so that the quantum dot bodies are connected to each other.

In an example, the plurality of thiol groups protected by the photolyzable group may be linked by a first connecting group. The first connecting group may be a flexible segment or a rigid chain segment. Further, the rigid chain segment may be a functional group for hole transport or electron transport, or a conjugated group that facilitates transport of holes and electrons. For example, the rigid chain segments may include triphenylamine structures, carbazole structures, or fluorene structures.

The quantum dot layer adopting the quantum dot composition is connected with the quantum dot body through an organic material. The organic material includes a ligand group coordinately connected with the quantum dot body and a crosslinking group connected with a plurality of ligand groups, and a thioether structure is formed between the ligand group and the crosslinking group. Wherein, the ligand in the quantum dot composition acts as a ligand group of the organic material after reacting with the released thiol group, sulfur free radical or sulfur anion, the first connecting group of the crosslinking agent can form a crosslinking group of the organic material, and the ligand group and the crosslinking group are connected by a thioether structure.

In an example, a structural formula of the quantum dot ligand is A-B-C-D or A-B-D; wherein, A is a coordination group capable of coordinately connected with the quantum dot body; B is a second connecting group; C is a carrier transport adjustment group; and D is the active alkenyl group.

Exemplarily, the coordination group may be selected from an amino group, a carboxylic acid group, a thiol group, a dithiol group, a phosphine group, or a phosphine oxide group.

Exemplarily, the second connecting group may be an alkyl chain containing 2-8 methylene groups, and the alkyl chain may be a linear alkyl chain or a branched alkyl chain.

Exemplarily, the carrier transport adjustment group is selected from a triphenylamine structure or a carbazole structure. The carrier transport adjustment group is disposed in the quantum dot ligand, so as to subsequently form a quantum dot layer with strong carrier transport capability. Triphenylamine structures and carbazole structures facilitate hole transport.

In an embodiment of the present disclosure, the active alkenyl group is selected from the group consisting of:

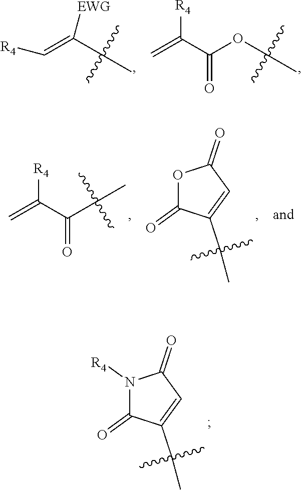

wherein R₄ is selected from the group consisting of hydrogen, deuterium and alkyl groups of 1 to 6 carbon atoms; EWG is an electron-withdrawing group.

For example, the active alkenyl group is selected from the group consisting of:

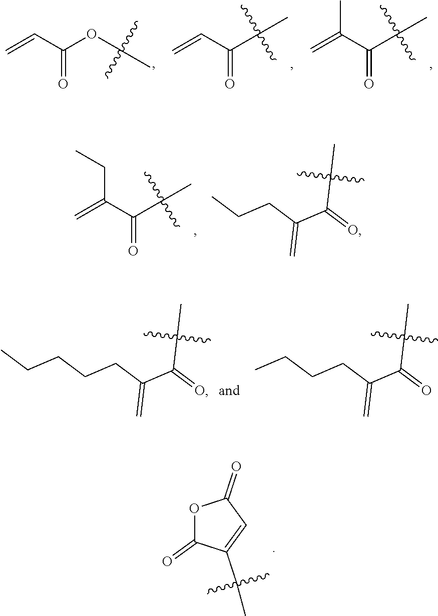

For example, the crosslinking agent contains two thiol groups protected by photolyzable groups and may have the following reaction:

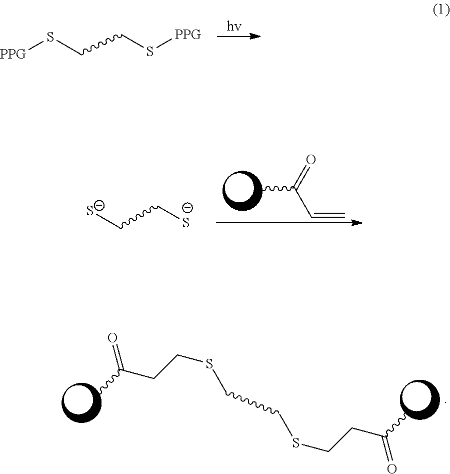

In an embodiment of the present disclosure, use [symbol] to represent a backbone structure connected to a functional group (e.g., thiol group protected by a photolyzable group, thiol group, sulfur free radical, sulfur anion, active alkenyl group, and the like) in the crosslinking agent or ligand. For example, use [symbol] to represent a first connecting group of a crosslinking agent or a non-functional moiety of a ligand. Use to represent a quantum dot body.

In Equation (1), the structure of the crosslinking agent may be:

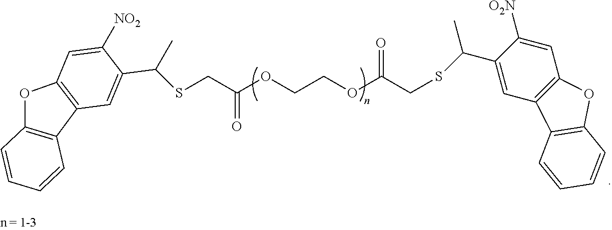

Optionally, the crosslinking agent may be synthesized by the following method:

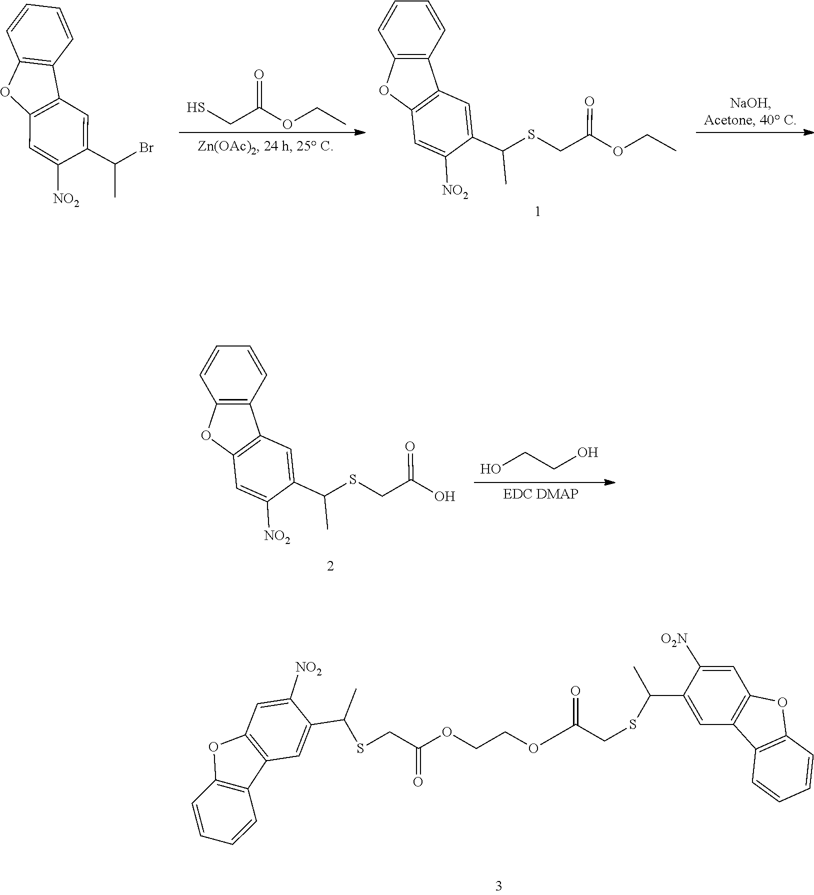

2-(1-Bromoethyl)-3-nitrodibenzofuran (0.64 g, 2 mmol) and ethyl thiol group acetate (0.24 g, 2 mmol) were dissolved in 10 mL of dichloromethane, and zinc acetate (0.36 g, 2 mmol) was added and stirred at 25° C. for 24 hours. Afterwards, add 50 mL of saturated sodium chloride solution to the reaction mixture, extract three times with dichloromethane, spin dry, and purify using column chromatography. Intermediate 1 (0.47 g, yield 65%) was obtained. ¹H NMR δ(ppm): 8.57 (1H), 7.98 (1H), 7.67 (1H), 7.54 (1H), 7.31-7.40 (2H), 4.17 (2H), 3.92 (1H), 3.40 (2H), 1.58 (3H), 1.25 (3H).

Intermediate 1 (0.36 g, 1 mmol) and sodium hydroxide (0.08 g, 2 mmol) were stirred in 10 mL of acetone at 40° C. for 4 hours. After cooling to room temperature, they were rotary evaporated and dried. 50 mL of saturated sodium chloride solution was added and extracted three times with dichloromethane before rotary evaporation and drying. Purification was carried out using column chromatography, followed by rotary evaporation drying to obtain Intermediate 2 (0.2 g, yield 60%). ¹H NMR δ(ppm): 8.59 (1H), 7.97 (1H), 7.64 (1H), 7.56 (1H), 7.31-7.40 (2H), 3.90 (1H), 3.40 (2H), 1.58 (3H).

Intermediate 2 (0.166 g, 0.5 mmol) and ethylene glycol (12.4 mg, 0.2 mmol) were added to 10 mL of dichloromethane. EDC (150 mg) (1-ethyl-(3-dimethylaminopropyl) carbodiimide) and DMAP (50 mg) (4-dimethylaminopyridine) were added and stirred at 25° C. for 12 hours. The mixture was then rotary evaporated and dried. 50 mL of saturated sodium chloride solution was added and extracted three times with dichloromethane before rotary evaporation and drying. Purification was carried out using column chromatography, followed by rotary evaporation drying to obtain compound 3 (68.8 g, yield 50%). ¹H NMR δ(ppm): 8.57 (2H), 7.98 (2H), 7.67 (2H), 7.54 (2H), 7.31-7.40 (4H), 4.31 (4H), 3.92 (2H), 3.40 (4H), 1.58 (6H).

In Equation (1), the structure of the quantum dot ligand may be:

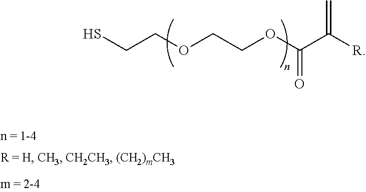

The coordination group in the quantum dot ligand is thiol group, and the second connecting group is an active alkenyl group.

In another example, the ligand in Equation (1) may also be:

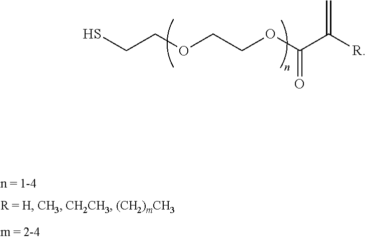

The coordination group in the quantum dot ligand is hydroxyl, and the second connecting group is

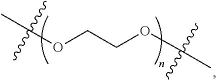

and the active alkenyl group is

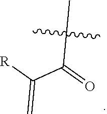

In the above example, it is an exemplary introduction based on the crosslinking agent having two reactive functional groups. Taking the crosslinking agent having three or more reactive functional groups as an example, an illustrative explanation will be given below.

In an example, the reaction between the crosslinking agent and the ligand is as follows:

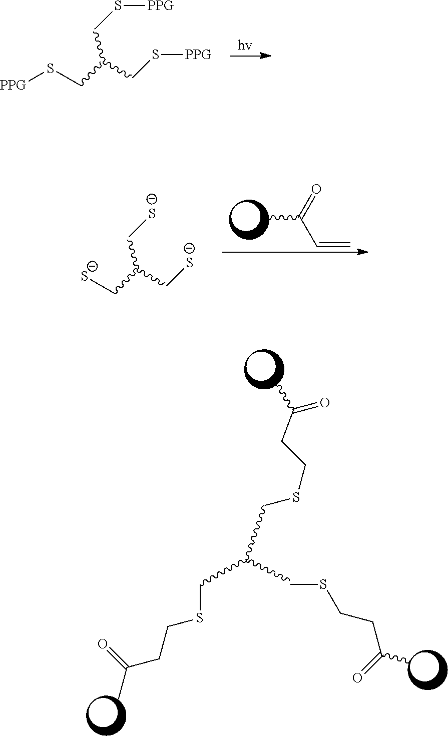

In this example, the crosslinking agent is:

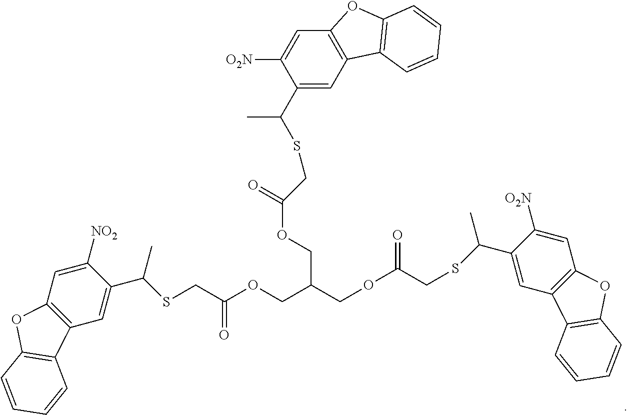 [SMILES: CC(SCC(=O)OCC(COC(=O)CSC(C)c1cc2c(cc1[N+](=O)[O-])oc1ccccc12)COC(=O)CSC(C)c1cc2c(cc1[N+](=O)[O-])oc1ccccc12)c1cc2c(cc1[N+](=O)[O-])oc1ccccc12]

The crosslinking agent can be synthesized by the following method:

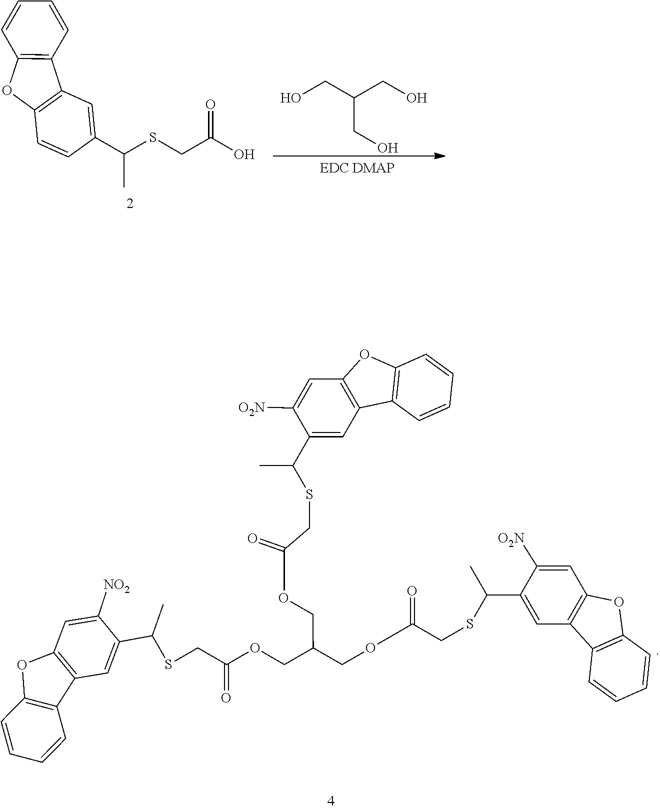 [SMILES: CC(SCC(=O)O)c1ccc2oc3ccccc3c2c1 ; OCC(CO)CO ; CC(SCC(=O)OCC(COC(=O)CSC(C)c1cc2c(cc1[N+](=O)[O-])oc1ccccc12)COC(=O)CSC(C)c1cc2c(cc1[N+](=O)[O-])oc1ccccc12)c1cc2c(cc1[N+](=O)[O-])oc1ccccc12]

Intermediate 2 (0.166 g, 0.5 mmol) and 2-hydroxymethyl-1,3-propanediol (16 mg, 0.15 mmol) were added to 10 mL of dichloromethane. EDC (150 mg) and DMAP (50 mg) were added and stirred at 25° C. for 12 hours. The mixture was then rotary evaporated and dried. 50 mL of saturated sodium chloride solution was added and extracted three times with dichloromethane before rotary evaporation and drying. Purification was carried out using column chromatography, followed by rotary evaporation drying to obtain product 4 (63 g, yield 40%). ¹H NMR δ(ppm): 8.57 (3H), 7.98 (3H), 7.67 (3H), 7.54 (3H), 7.31-7.40 (6H), 4.31 (6H), 3.92 (3H), 3.40 (6H), 1.58 (9H), 1.21 (1H).

In an example, the reaction between the crosslinking agent and the ligand is as follows:

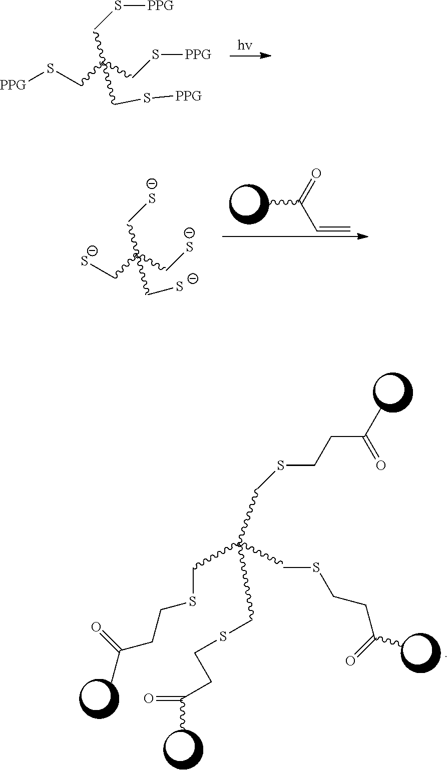

In this example, the crosslinking agent is:

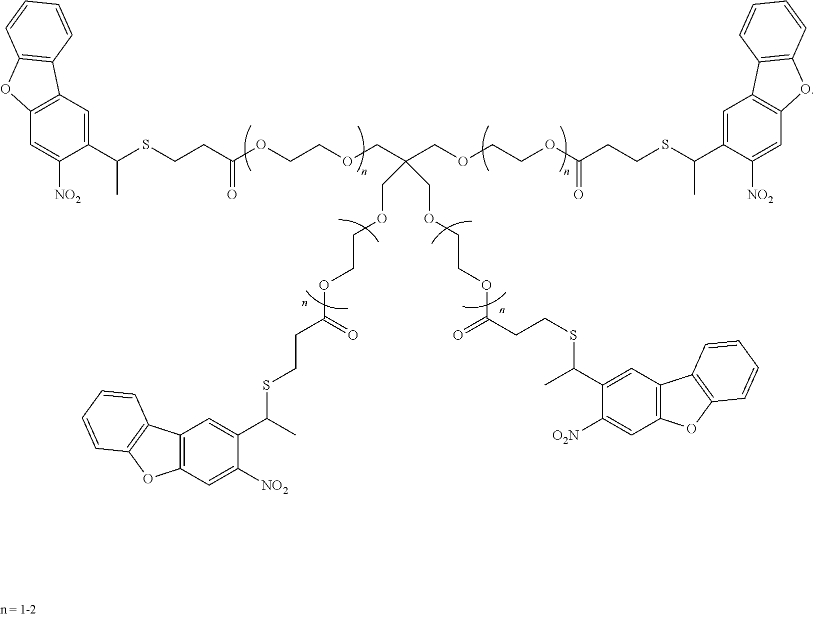

The crosslinking agent can be synthesized by the following method:

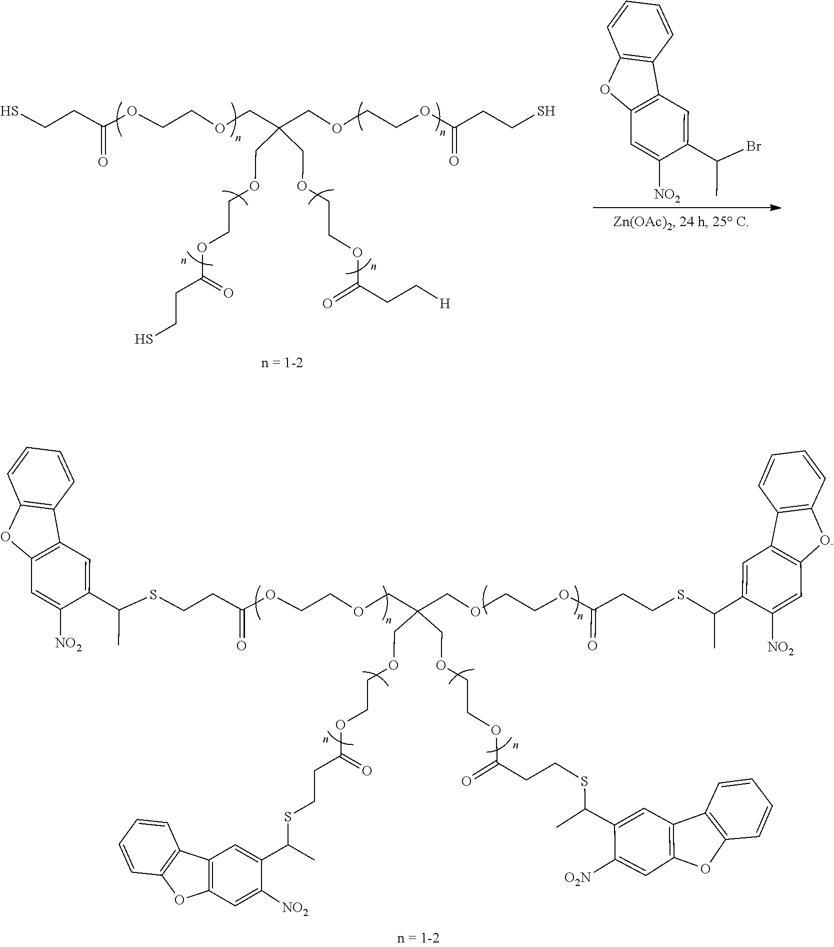

In another embodiment of the present disclosure, the quantum dot ligand has the thiol group protected by photolyzable group; the crosslinking agent has a plurality of active alkenyl groups, and the active alkenyl group has an alkenyl group and an electron-withdrawing group connected to the alkenyl group.

Optionally, the crosslinking agent has a first connecting group, and the active alkenyl group is attached to the first connecting group.

In the quantum dot layer using the quantum dot composition, the quantum dots are connected with each other through organic materials. The organic material includes a ligand group coordinately connected with the quantum dot body and a crosslinking group connected with a plurality of ligand groups, and a thioether structure is formed between the ligand group and the crosslinking group. The crosslinking agent in the quantum dot composition forms a crosslinking group of the organic material after reacting with thiol group, sulfur free radical or sulfur anion on the ligand, and the part of the ligand in the quantum dot composition for connecting the thiol group, the sulfur free radical or the sulfur anion and the quantum dot body may form a ligand group of the organic material, and the ligand group and the crosslinking group are connected by a thioether structure.

Optionally, a structural formula of the quantum dot ligand is A-B-C-D or A-B-D; wherein, A is a coordination group capable of coordinately connected with the quantum dot body; B is a second connecting group; C is a carrier transport adjustment group; and D is a thiol group protected by photolyzable group.

In an example, the crosslinking agent reacts with the ligand as follows:

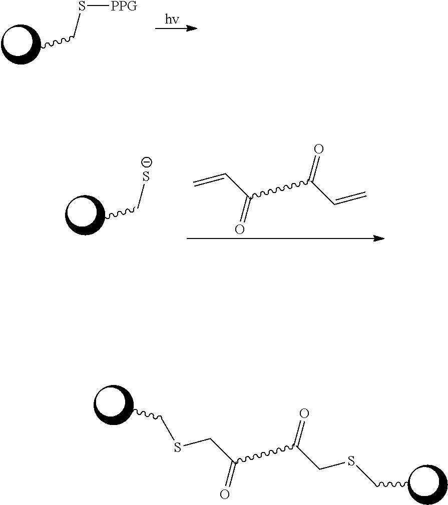

In this example, the crosslinking agent is:

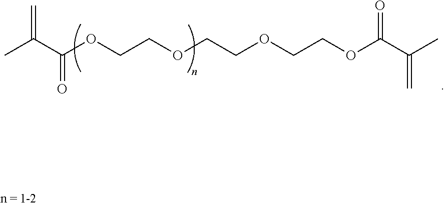

In this example, the ligand is:

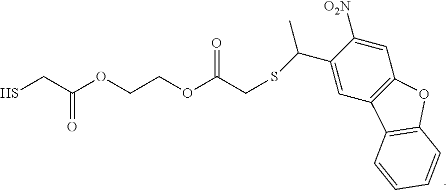 [SMILES: CC(SCC(=O)OCCOC(=O)CS)c1cc2c(cc1[N+](=O)[O-])oc1ccccc12]

The ligand can be synthesized by the following method:

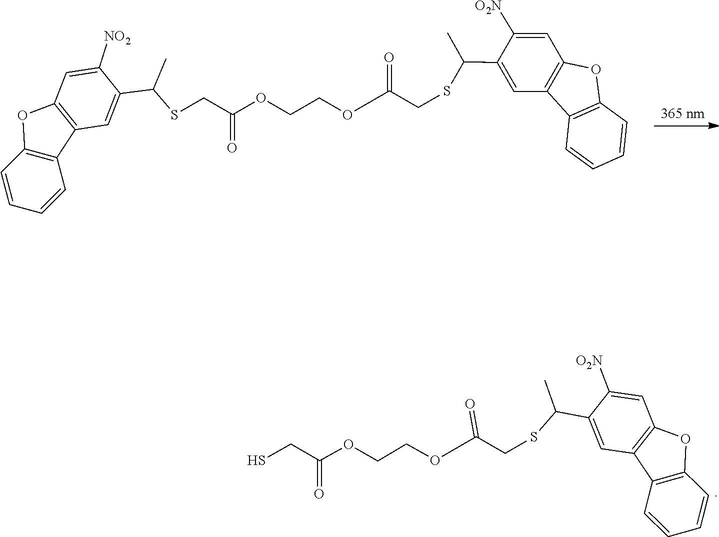 [SMILES: CC(SCC(=O)OCCOC(=O)CSC(C)c1cc2c(cc1[N+](=O)[O-])oc1ccccc12)c1cc2c(cc1[N+](=O)[O-])oc1ccccc12 ; CC(SCC(=O)OCCOC(=O)CS)c1cc2c(cc1[N+](=O)[O-])oc1ccccc12]

In another example, the crosslinking agent reacts with the ligand as follows:

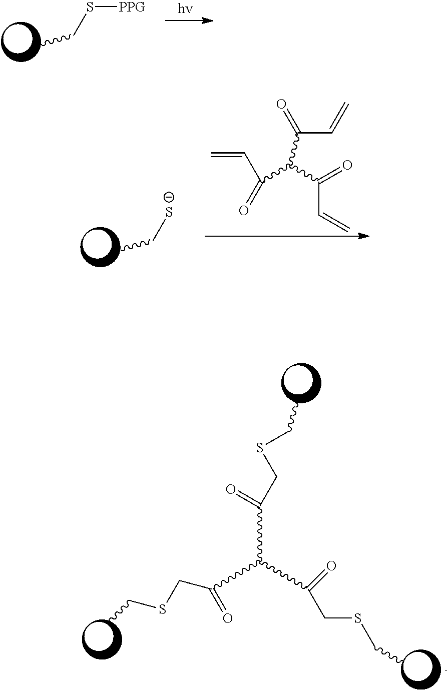

Exemplary crosslinking agents may be:

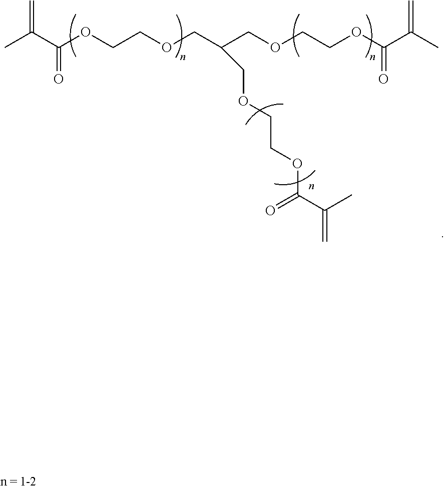

In another example, the crosslinking agent reacts with the ligand as follows:

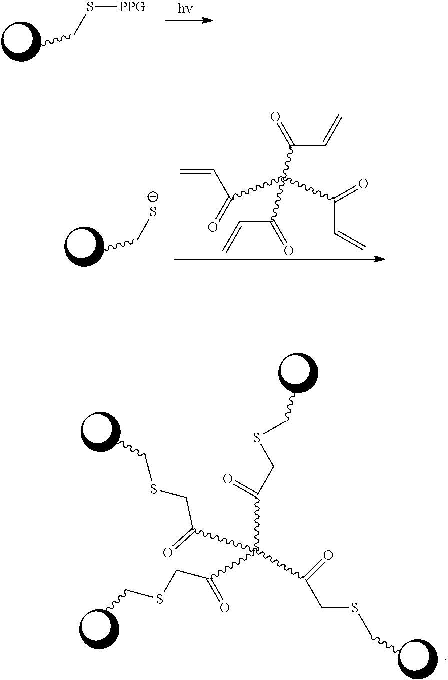

Exemplary crosslinking agents may be:

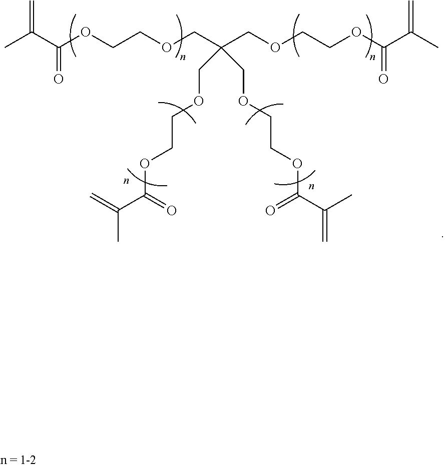

In another embodiment, the crosslinking agent has a plurality of thiol groups protected by photolyzable groups; and in the quantum dot body and the ligand, a mass ratio of the ligand is not greater than 30%. In this embodiment, the thiol group, sulfur free radical or sulfur anion released by the crosslinking agent may be directly connected to the quantum dot body, so as to crosslink the quantum dot bodies.

In an example, in the quantum dot body and the ligand, a mass ratio of the ligand is not greater than 15%.

In another example, in the quantum dot body and the ligand, the mass ratio of the ligand is between 15% and 30%; the acidity of the ligand is less than the acidity of the thiol group protected by photolyzable group after deprotection.

In an example, the quantum dot ligand is selected from oleic acid, oleylamine, octanethiol group, and dodecanethiol group.

In another example, the crosslinking agent reacts directly with the quantum dot body after deprotection, and the reaction formula is as follows:

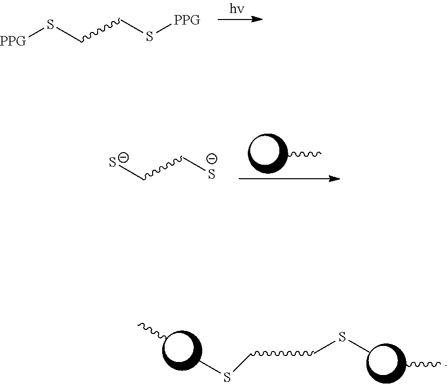

In an embodiment of the present disclosure, the mass content of the crosslinking agent is 1% to 5%. Of course, the amount of crosslinking agent can also be increased or decreased as needed.

In an embodiment of the present disclosure, the quantum dot composition further includes a solvent, for example, including PGMEA (propylene glycol methyl ether acetate) or toluene, hexane, octane, or a combination thereof. In an example, the concentration of the quantum dots is 10-100 mg/mL.

The embodiments of the present disclosure also verify the crosslinking capability of the quantum dot composition under light. Specifically, an experimental quantum dot composition containing a crosslinking agent and a control quantum dot composition without a crosslinking agent are provided. The structure of the cross-linking agent and the ligand is as follows, and the quantum dot body is a red quantum dot body.

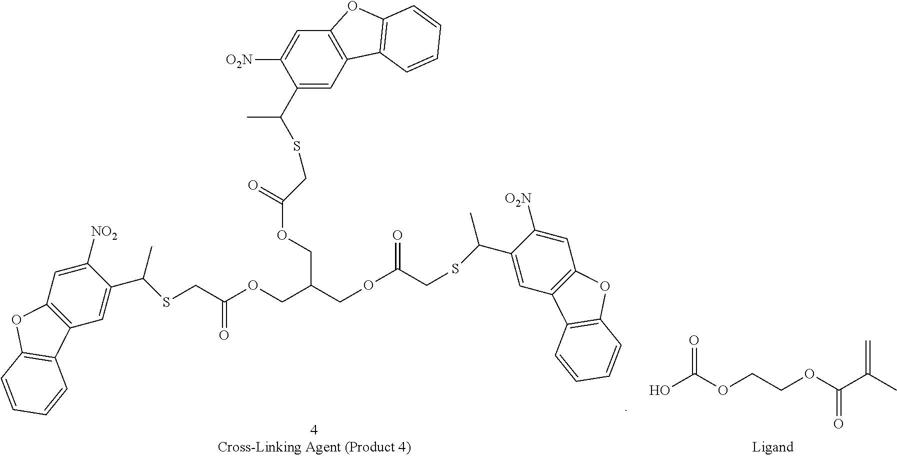 [SMILES: CC(SCC(=O)OCC(COC(=O)CSC(C)c1cc2c(cc1[N+](=O)[O-])oc1ccccc12)COC(=O)CSC(C)c1cc2c(cc1[N+](=O)[O-])oc1ccccc12)c1cc2c(cc1[N+](=O)[O-])oc1ccccc12 ; C=C(C)C(=O)OCCOC(=O)O]

A hole transport material is first coated on the glass substrate, and the hole transport material can be excited to emit blue light under ultraviolet irradiation. Then, a control quantum dot composition is coated on the surface of the hole transport material layer and exposed and developed; and ultraviolet light is irradiated after development, referring to FIG. 9, the surface of the glass substrate is blue. This indicates that the glass substrate surface has no red quantum dot body, and the control quantum dot composition is not crosslinked.

A hole transport material is first coated on the glass substrate, and the hole transport material can be excited to emit blue light under ultraviolet irradiation. Then, an experimental quantum dot composition is coated on the surface of the hole transport material layer and exposed and developed; and ultraviolet light is irradiated after development, referring to FIG. 10, the surface of the glass substrate is red. This indicates that the red quantum dot body is fixed on the surface of the hole transport material layer, and the experimental quantum dot composition is crosslinked.

The present disclosure further provides a light-emitting element, the light-emitting element includes a quantum dot layer, and the quantum dot layer has a quantum dot body connected to each other by an organic material;

Wherein, the organic material includes a ligand group coordinately connected with the quantum dot body and a crosslinking group connected with a plurality of ligand groups, and a thioether structure is formed between the ligand group and the crosslinking group; or the organic material has a plurality of thiol groups, sulfur free radicals or sulfur anions and is coordinately connected with a plurality of quantum dot bodies through thiol group, sulfur free radical or sulfur anion.

Optionally, the quantum dot solution having the quantum dot composition provided in the embodiments of the present disclosure may be patterned with light to form the quantum dot layer of the light-emitting element.

The present disclosure further provides a preparation method of a display panel, including: forming a quantum dot layer of at least two sub-pixels sequentially through a photolithography process on a surface of a substrate; for example, sequentially forming three quantum dot layers such as a red quantum dot layer, a green quantum dot layer, and a blue quantum dot layer.

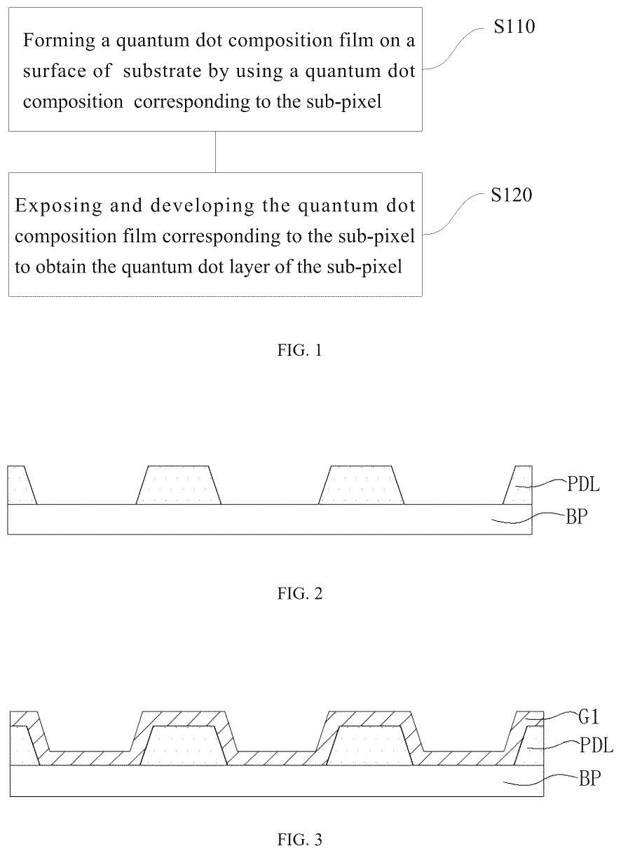

Referring to FIG. 1, forming a quantum dot layer of any of the sub-pixels includes:

Step S110, forming a quantum dot composition film on a surface of a substrate by using a quantum dot composition corresponding to the sub-pixel, where the quantum dot composition is selected from the quantum dot composition described above;

Step S120, exposing and developing the quantum dot composition film corresponding to the sub-pixel to obtain the quantum dot layer of the sub-pixel.

Quantum dots in quantum dot compositions corresponding to quantum dot layers of different sub-pixels are different. For example, when preparing the red quantum dot layer, the quantum dot body in the quantum dot composition is a red quantum dot body. When preparing the green quantum dot layer, the quantum dot body in the quantum dot composition is a green quantum dot body. When preparing the blue quantum dot layer, the quantum dot body in the quantum dot composition is a blue quantum dot body.

In an embodiment of the present disclosure, the preparation method of the display panel further includes:
forming a hole transport layer of each of the sub-pixels before forming the quantum dot layer.

In an embodiment of the present disclosure, the preparation method of the display panel further includes:
forming an electron transport layer of each of the sub-pixels after forming the quantum dot layer of each of the sub-pixels.

In an embodiment of the present disclosure, forming the quantum dot composition film on the surface of the substrate by using the quantum dot composition corresponding to the sub-pixel includes:
forming the quantum dot composition film on the surface of the substrate by a coating process by using the quantum dot composition corresponding to the sub-pixel.

The preparation method of the quantum dot layer provided by the embodiments of the present disclosure will be exemplarily described below with reference to the accompanying drawings.

Step S210, preparing quantum dot solutions of three different colors, wherein the quantum dot solution includes quantum dot compositions of different colors and a solvent thereof.

For example, when preparing the red quantum dot solution, a red quantum dot body is used. When preparing the green quantum dot solution, a green quantum dot body is used. When preparing the blue quantum dot solution, the blue quantum dot body is used.

Any quantum dot solution may be prepared by using the following exemplary method: dissolving a quantum dot body (CdSe/ZnSe quantum dot) modified with a ligand into a solvent (for example, n-octane or PGMEA), wherein the mass concentration of the quantum dot body in the solution is 30 mg/mL. The desired crosslinking agent is added to the quantum dot solution.

Step S220, coating a green quantum dot solution on the substrate, adding a first mask, and exposing the whole with ultraviolet light. After exposure, PGMEA or toluene is used as a developer for rinsing and development. After development, the substrate is heated in a 90° C. environment for 120 seconds to remove the developer and obtain a patterned green quantum dot layer.

Step S230, coating a blue quantum dot solution on the substrate, adding a second mask, and exposing the whole with ultraviolet light. After exposure, PGMEA or toluene is used as a developer for rinsing and development. After development, the substrate is heated in a 90° C. environment for 120 seconds to remove the developer and obtain a patterned blue quantum dot layer.

Step S240, coating a red quantum dot solution on the substrate, adding a third mask, and exposing the whole with ultraviolet light. After exposure, PGMEA or toluene is used as a developer for rinsing and development. After development, the substrate is heated in a 90° C. environment for 120 seconds to remove the developer and obtain a patterned red quantum dot layer.

In step S220 to step S240, the green quantum dot solution layer, the blue quantum dot solution and the red quantum dot solution may be respectively patterned through the first mask, the second mask, and the third mask to obtain a patterned green quantum dot layer, a patterned blue quantum dot layer, and a patterned red quantum dot layer. The positions and shapes of the three different quantum dot layers can be controlled by controlling the light-transmitting regions of the first mask, the second mask and the third mask.

The preparation method of the display panel provided by the embodiments of the present disclosure will be exemplarily described below with reference to the accompanying drawings.

Step S310, referring to FIG. 2, providing a back plate BP. Optionally, the back plate BP includes a base substrate and a driving layer which are sequentially stacked, and the driving layer has a transistor layer and a source-drain metal layer. Each film of the driving layer may be sequentially prepared from the base substrate, for example, a gate layer (for example, a material of molybdenum, a thickness of 200 nm), a gate insulating layer (for example, 150 nm thick silicon oxide), a semiconductor layer (for example, IGZO with a thickness of 40 nm), a source/drain metal layer (for example, a material of molybdenum, a thickness of 200 nm), and a passivation layer (for example, silicon oxide with a thickness of 300 nm).

Further, a pixel electrode layer (for example, a material of ITO and a thickness of 40 nm) and a pixel definition layer PDL (for example, 1.5 micrometer thick acrylic) may be sequentially formed on the back plate.

Step S320, cleaning the surface of the back plate. For example, a plasma treatment is used to clean the surface of the back plate.

Step S330, preparing a first common material layer on the surface of the backplane, for example, preparing a hole injection layer and a hole transport layer of each sub-pixel. In an example, the hole injection layer and the hole transport layer may be prepared by a spin coating process, such as spin coating PEDOT: PSS (hole injection layer) and TFB (hole transport layer), respectively. Further, an overall thickness of the hole injection layer and the hole transport layer is 50-100 nm.

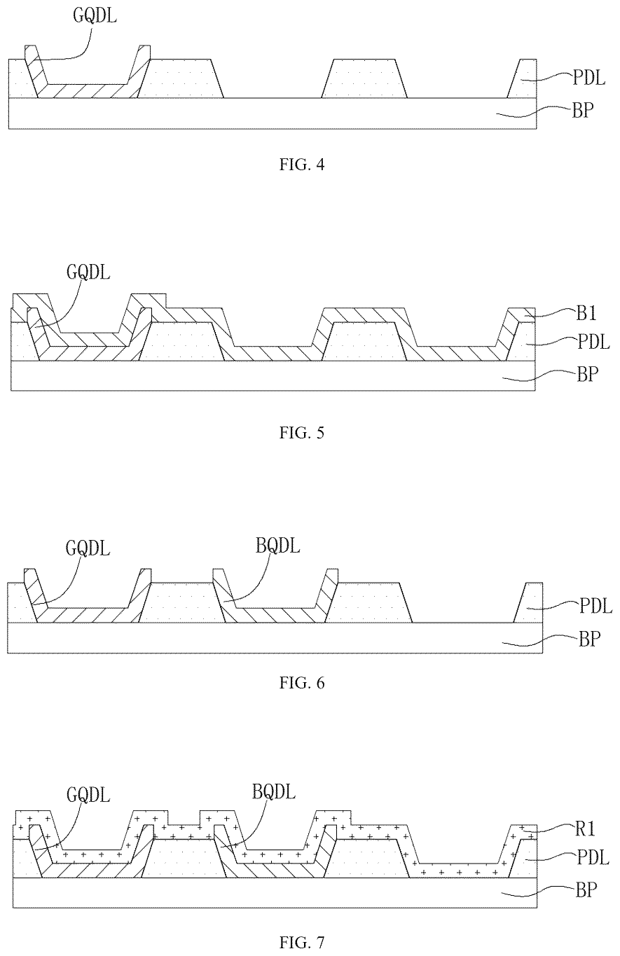

Step S340, referring to FIG. 3 and FIG. 4, preparing a green quantum dot layer GQDL on the surface of the back plate BP. For example, coating a green quantum dot solution on the back plate to form a green quantum dot composite layer G1, adding a first mask, and exposing the whole with ultraviolet light. After exposure, PGMEA or toluene is used as a developer for rinsing and development. After development, heat the back plate in a 90° C. environment for 120 seconds to remove the developer and obtain a patterned green quantum dot layer GQDL.

Step S350, referring to FIG. 5 and FIG. 6, preparing a blue quantum dot layer BQDL on the surface of the back plate BP. For example, coating a blue quantum dot solution on the back plate to form a blue quantum dot composition layer B1, adding a second mask, and the exposing the whole with ultraviolet light. After exposure, PGMEA or toluene is used as a developer for rinsing and development. After development, the back plate is heated in a 90° C. environment for 120 seconds to remove the developer to obtain a patterned blue quantum dot layer BQDL.

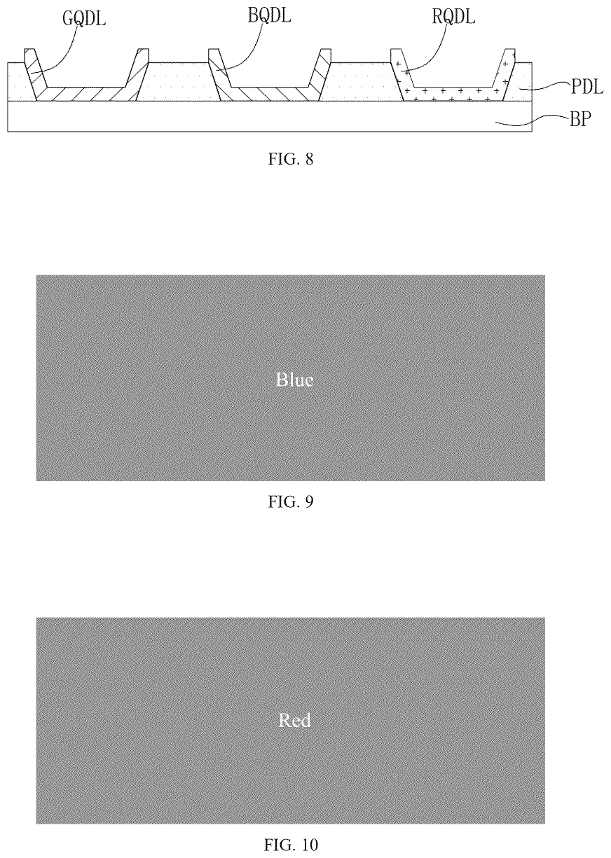

Step S360, referring to FIG. 7 and FIG. 8, preparing a red quantum dot layer RQDL on the surface of the back plate BP. For example, coating a red quantum dot solution on the back plate to form a red quantum dot composition layer R1, adding a third mask, and exposing the whole with ultraviolet light. After exposure, PGMEA or toluene is used as a developer for rinsing and development. After development, the back plate is heated in a 90° C. environment for 120 seconds to remove the developer to obtain a patterned red quantum dot layer RQDL.

Step S370, after forming each quantum dot layer, preparing a second common material layer. The second common material layer includes, but is not limited to, an electron transport layer (such as ZnO nanoparticles) and an electron injection layer. The second common material layer may be formed by spin coating or evaporation.

Step S380, forming a cathode. For example, the cathode metal thin layer may be evaporated, and the cathode may be an Al layer or the like, which is about 500-1000 nm.

After the evaporation is completed, packaging and cutting are carried out to complete the preparation of the entire AMQLED display panel.

In an example, the prepared display panel is a bottom-emitting display panel.

In an example, the minimum size of the sub-pixel may be in a range of 10 μm to 30 μm, which makes the resolution of the display panel reach 300-800 PPI.

Optionally, when the display panel is prepared, there may be gaps between the quantum dot layers of two adjacent sub-pixels, or may overlap with each other.

In an example, when the display panel is prepared, the quantum dot layer is located in a pixel opening formed by the pixel defining layer.

In another example, when the display panel is prepared, at least part of an edge of the quantum dot layer is located outside the pixel opening formed by the pixel definition layer.

In some other embodiments of the present disclosure, the quantum dot body in the quantum dot composition may further be replaced with nanoparticles such as ZnO, ZnMgO, ZnAlO, ZnLiO and the like to form an electron transport material composition, and the electron transport material composition may form an electron transport layer by using a photolithography process. Of course, when the electron transport layer does not need to be patterned, the film formed by the electron transport material composition may be cured by light.

Other embodiments of the present disclosure will be apparent to those skilled in the art from consideration of the specification and practice of the present disclosure disclosed herein. The present application is intended to cover any variations, uses, or adaptations of the present disclosure, which are in accordance with the general principles of the present disclosure and include common general knowledge or conventional technical means in the art that are not disclosed in the present disclosure. The specification and embodiments are illustrative, and the real scope and spirit of the present disclosure is defined by the appended claims.

1. A quantum dot composition is provided, comprising a quantum dot body, a ligand, and a crosslinking agent;
wherein the ligand is coordinately connected with the quantum dot body;
one of the ligand and the crosslinking agent has a thiol group protected by a photolyzable group;
the photolyzable group can be removed under light to release the thiol group, a sulfur free radical or a sulfur anion;
when the released the thiol group, sulfur free radical or sulfur anion is located on the crosslinking agent, the released thiol group, sulfur free radical or sulfur anion is used for coordinately connecting with the quantum dot body or used for reacting with the ligand to form a chemical bond; when the released thiol group, sulfur free radical or sulfur anion is located on the ligand, the released thiol group, sulfur free radical or sulfur anion is used for reacting with the crosslinking agent to form a chemical bond.

2. The quantum dot composition according to claim 1, wherein the photolyzable group is selected from the following substituents: 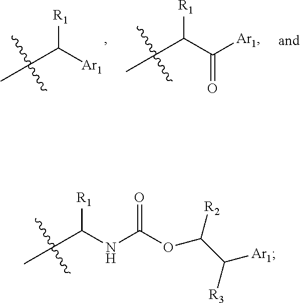
wherein Ar₁ is selected from an aryl group having a nitro group or a hydroxyl group, a heteroaryl group having a nitro group and a hydroxyl group; R₁, R₂ and R₃ are each independently selected from hydrogen, deuterium and an alkyl group having a carbon atom number of 1 to 6.

3. The quantum dot composition according to claim 2, wherein the photolyzable group is selected from the following substituents: 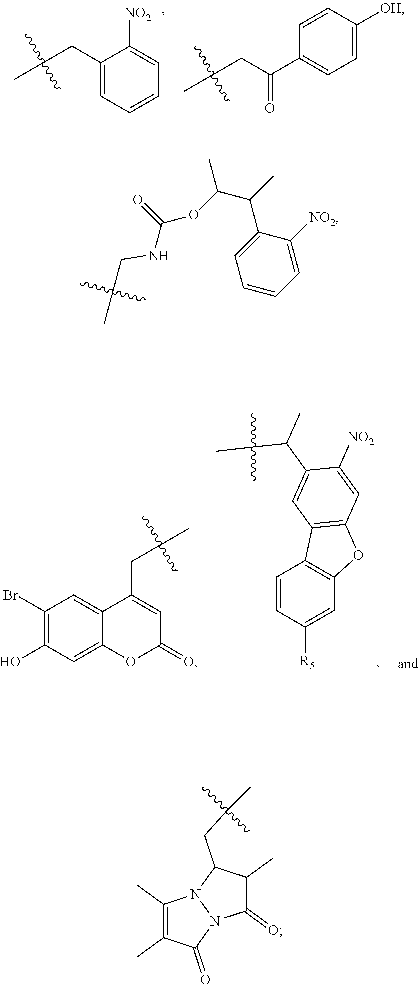
wherein R₅ is selected from hydrogen, deuterium, and alkoxy having a carbon atom of 1 to 8.

4. The quantum dot composition according to claim 1, wherein the crosslinking agent has a plurality of thiol groups protected by the photolyzable group; the ligand has an active alkenyl group, and the active alkenyl group has an alkenyl group and an electron-withdrawing group connected to the alkenyl group.

5. The quantum dot composition according to claim 4, wherein the crosslinking agent has a first connecting group, and the thiol group protected by photolyzable group is attached to the first connecting group.

6. The quantum dot composition according to claim 4, wherein a structural formula of the ligand is A-B-C-D or A-B-D; wherein, A is a coordination group capable of coordinately connected with the quantum dot; B is a second connecting group; and C is a carrier transport adjustment group; D is the active alkenyl group.

7. The quantum dot composition according to claim 1, wherein the ligand has the thiol group protected by photolyzable group; the crosslinking agent has a plurality of active alkenyl groups, and the active alkenyl group has an alkenyl group and an electron-withdrawing group connected to the alkenyl group.

8. The quantum dot composition according to claim 7, wherein the crosslinking agent has a first connecting group, and the active alkenyl group is attached to the first connecting group.

9. The quantum dot composition according to claim 7, wherein a structural formula of the ligand is A-B-C-D or A-B-D; wherein, A is a coordination group capable of coordinately connected with the quantum dot; B is a second connecting group; C is a carrier transport adjustment group; D is the thiol group protected by photolyzable group.

10. The quantum dot composition according to claim 6, wherein the coordination group has an amino group, a carboxylic acid group, a thiol group, two thiol groups, a phosphine group, or a phosphine oxide group.

11. The quantum dot composition according to claim 4, wherein the active alkenyl group is selected from the group consisting of: 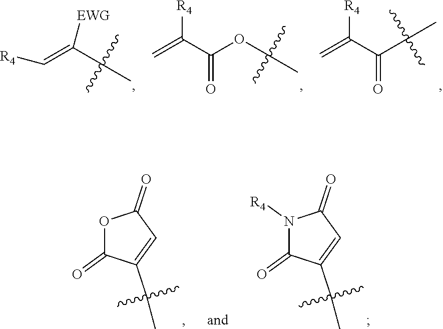
wherein R₄ is selected from the group consisting of hydrogen, deuterium and alkyl groups of 1 to 6 carbon atoms; EWG is an electron-withdrawing group.

12. The quantum dot composition according to claim 11, wherein the active alkenyl group is selected from the group consisting of:

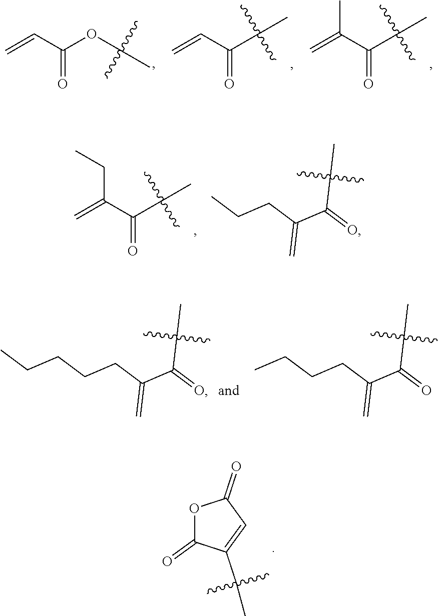

13. The quantum dot composition according to claim 1, wherein the crosslinking agent has a plurality of thiol groups protected by the photolyzable group;
in the quantum dot body and the ligand, the mass ratio of the ligand is not greater than 30%.

14. The quantum dot composition according to claim 13, wherein in the quantum dot body and the ligand, the mass ratio of the ligand is not greater than 15%.

15. The quantum dot composition according to claim 13, wherein in the quantum dot body and the ligand, the mass ratio of the ligand is between 15% and 30%;
the acidity of the ligand is less than the acidity of the thiol group protected by photolyzable group after deprotection.

16. The quantum dot composition according to claim 13, wherein the ligand is selected from oleic acid, oleylamine, octanethiol group, and dodecanethiol group.

17. The quantum dot composition according to claim 1, wherein the mass content of the crosslinking agent is 1% to 5%.

18. A light-emitting element, comprising a quantum dot layer which comprises quantum dot bodies connected to each other by organic materials;
wherein the organic material comprises a ligand group coordinately connected with the quantum dot body and a crosslinking group connected with a plurality of ligand groups, and a thioether structure is formed between the ligand group and the crosslinking group; or the organic material has a plurality of thiol groups, sulfur free radicals or sulfur anions and is coordinately connected with a plurality of quantum dot bodies through thiol groups, sulfur free radicals or sulfur anions.

19. A display panel, comprising the light-emitting element according to claim 18.

20. A preparation method of a display panel, comprising: forming a quantum dot layer of at least two sub-pixels sequentially through a photolithography process on a surface of a substrate; wherein forming a quantum dot layer of any of the sub-pixels comprises:
forming a quantum dot composition film on a surface of the substrate by using a quantum dot composition corresponding to the sub-pixel;
exposing and developing the quantum dot composition film corresponding to the sub-pixel to obtain a quantum dot layer of the sub-pixel;
wherein, quantum dots in quantum dot compositions corresponding to quantum dot layers of different sub-pixels are different;
wherein the quantum dot composition comprises a quantum dot body, a ligand, and a crosslinking agent;
the ligand is coordinately connected with the quantum dot body;
one of the ligand and the crosslinking agent has a thiol group protected by a photolyzable group;
the photolyzable group can be removed under light to release the thiol group, a sulfur free radical or a sulfur anion;
when the released the thiol group, sulfur free radical or sulfur anion is located on the crosslinking agent, the released thiol group, sulfur free radical or sulfur anion is used for coordinately connecting with the quantum dot body or used for reacting with the ligand to form a chemical bond; when the released thiol group, sulfur free radical or sulfur anion is located on the ligand, the released thiol group, sulfur free radical or sulfur anion is used for reacting with the crosslinking agent to form a chemical bond.

21.-23. (canceled)
